(19) United States
(12) Patent Application Publication
(10) Pub. No.: US 2024/0305251 A1
(43) Pub. Date: Sep. 12, 2024

(54) SAMPLING CIRCUIT

(71) Applicant: LAPIS Technology Co., Ltd., Yokohama (JP)

(72) Inventor: Riku TATETSU, Yokohama (JP)

(73) Assignee: LAPIS Technology Co., Ltd., Yokohama (JP)

(21) Appl. No.: 18/595,328

(22) Filed: Mar. 4, 2024

(30) Foreign Application Priority Data
Mar. 6, 2023 (JP) 2023-033999

(51) Int. Cl. H03F 3/16

(52) U.S. Cl. CPC H03F 3/16; H03F 2200/129

(57) ABSTRACT

A sampling circuit includes: an amplifier, having a characteristic that settling time in a case where an output voltage of the sampling circuit is lowered and the settling time in a case where the output voltage is raised are different; a capacitor, charged by an input voltage from the amplifier; a first switch, switching a connection state between an output of the amplifier and the capacitor; a second switch, connected in parallel with the capacitor, and switching a connection state between the capacitor and a reference potential part whose potential is set according to the characteristic of the amplifier; and a control circuit, controlling switching of each switch. The control circuit performs a first control that switches the first switch off and the second switch on and then performs a second control that switches the first switch on and the second switch off.

### CROSS-REFERENCE TO RELATED APPLICATIONS

This application claims the priority benefit of Japan Application No. 2023-033999, filed on Mar. 6, 2023. The entirety of the above-described patent application is hereby incorporated by reference herein and made a part of the present specification.

### BACKGROUND

### Technical field

The present disclosure relates to a sampling circuit and a control method thereof.

### Related Art

There is a problem that an output voltage of a sampling circuit fluctuates due to charges accumulated in a capacitor included in the sampling circuit. To solve this problem, for example, in a circuit described in Japanese Patent Laid-Open No. H7-21794, a switch S1 for discharging is provided that discharges charges of a capacitor Cc of a high-pass filter. The switch S1 is turned on for a certain period of time before a sampling switch Ss is turned on, and the capacitor Cc is discharged.

However, as a result of detailed study by the inventor, the following problem was found in a case where a voltage is input to a sampling circuit from an amplifier. In the case where a voltage is input to a sampling circuit from an amplifier, depending on the amplifier, settling time may increase even if the capacitor is discharged. Here, the settling time is the time required until an output voltage stabilizes at a target value.

### SUMMARY

A first aspect of the present disclosure provides a sampling circuit including: an amplifier, having a characteristic that settling time in a case where an output voltage of the sampling circuit is lowered and the settling time in a case where the output voltage is raised are different; a capacitor, charged by an input voltage from the amplifier; a first switch, switching a connection state between an output of the amplifier and the capacitor; a second switch, connected in parallel with the capacitor, and switching a connection state between the capacitor and a reference potential part whose potential is set according to the characteristic of the amplifier; and a control circuit, controlling switching of the first switch and the second switch. The control circuit performs a first control that switches the first switch to an off state and the second switch to an on state, connects the capacitor to the reference potential part, and sets a voltage of the capacitor to a reference potential corresponding to the characteristic of the amplifier. After a predetermined time has elapsed from the first control, the control circuit performs a second control that switches the first switch to the on state and the second switch to the off state, connects the amplifier to the capacitor, and charges the capacitor by the input voltage of the amplifier.

A second aspect of the present disclosure provides a sampling circuit including: a voltage source, inputting a first voltage; an amplifier, inputting a second voltage, and having a characteristic that settling time in a case where an output voltage of the sampling circuit is lowered and the settling time in a case where the output voltage is raised are different; a capacitor, charged by an input voltage from the voltage source or the amplifier; a first switch, switching a connection state between the voltage source and the capacitor; a second switch, switching a connection state between the amplifier and the capacitor; a third switch, connected in parallel with the capacitor, and switching a connection state between the capacitor and a reference potential part whose potential is set according to the characteristic of the amplifier; and a control circuit, controlling switching of the first switch, the second switch, and the third switch. The control circuit performs a first control that switches the first switch to an on state, the second switch to an off state, and the third switch to an off state, connects the voltage source to the capacitor, and charges the capacitor to the first voltage. After a predetermined time has elapsed from the first control, the control circuit performs a second control that switches the first switch to the off state, the second switch to the off state, and the third switch to the on state, connects the capacitor to the reference potential part, and changes a voltage of the capacitor from the first voltage to a reference potential corresponding to the characteristic of the amplifier. After a predetermined time has elapsed from the second control, the control circuit performs a third control that switches the first switch to the off state, the second switch to the on state, and the third switch to the off state, connects the amplifier to the capacitor, and charges the capacitor to the second voltage.

### BRIEF DESCRIPTION OF THE DRAWINGS

FIG. 1 is a circuit diagram illustrating a basic configuration of a sampling circuit of the present disclosure.

FIG. 2A to FIG. 2D are schematic diagrams for describing characteristics of an amplifier.

FIG. 3 is a circuit diagram illustrating an example of a configuration of a sampling circuit according to a first embodiment of the present disclosure.

FIG. 4 is a graph illustrating an example of an operation state of a conventional sampling circuit.

FIG. 5 is a graph illustrating an example of an operation state of the sampling circuit according to the first embodiment.

FIG. 6 is a circuit diagram illustrating a modification of the sampling circuit according to the first embodiment.

FIG. 7 is a circuit diagram illustrating an example of a configuration of a sampling circuit according to a second embodiment of the present disclosure.

FIG. 8 is a graph illustrating an example of an operation state of a conventional sampling circuit.

FIG. 9 is a graph illustrating an example of an operation state of the sampling circuit according to the second embodiment.

FIG. 10 is a circuit diagram illustrating a modification of the sampling circuit according to the second embodiment.

### DESCRIPTION OF THE EMBODIMENTS

The present disclosure provides a sampling circuit and a control method thereof, in which even if a voltage is input to the sampling circuit from an amplifier, settling time can be shortened and the time until sampling is started can be reduced.

According to the present disclosure, even if a voltage is input from the amplifier, the settling time can be shortened and the time until sampling is started can be reduced.

Hereinafter, an example of an embodiment of the present disclosure will be described in detail with reference to the drawings.

### Basic Configuration

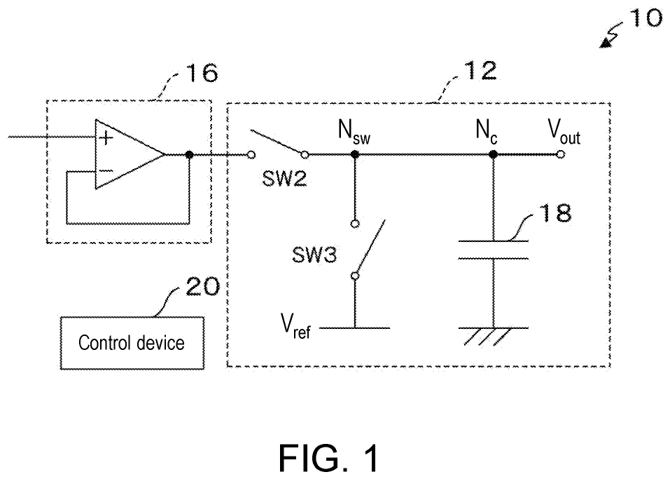

First, with reference to FIG. 1, a basic configuration of a sampling circuit of the present disclosure is described.

A sampling circuit 10 includes a sampling circuit part 12, and an amplifier 16 connected to an input terminal of the sampling circuit part 12. The sampling circuit part 12 includes a switch SW2, a switch SW3, and a capacitor 18. The sampling circuit 10 includes a control device 20 that controls on/off of each of the switch SW2 and the switch SW3.

The switch SW2 is a switch that switches input from the amplifier 16. In the sampling circuit 10, when the switch SW2 is turned on, an input voltage input from the amplifier 16 is output from the sampling circuit 10. The capacitor 18 is charged by the input voltage from the amplifier 16. On the other hand, when the switch SW2 is turned off, a holding voltage of the capacitor 18 is output from the sampling circuit 10.

The switch SW3 is a switch for adjusting the holding voltage of the capacitor 18. Before the switch SW2 is turned on, the switch SW3 is turned on, the capacitor 18 is connected to a reference potential part, and the holding voltage becomes equal to a potential of the reference potential part, that is, reference potential V_{ref}. When the reference potential V_{ref} is ground (GND), the capacitor 18 is discharged and the holding voltage becomes 0 V. When the reference potential V_{ref} (for example, 5 V) is higher than the input voltage, the potential of the capacitor 18 is pulled up and the holding voltage becomes 5 V. The reference potential V_{ref} is set according to amplifier characteristics.

### Amplifier Characteristics

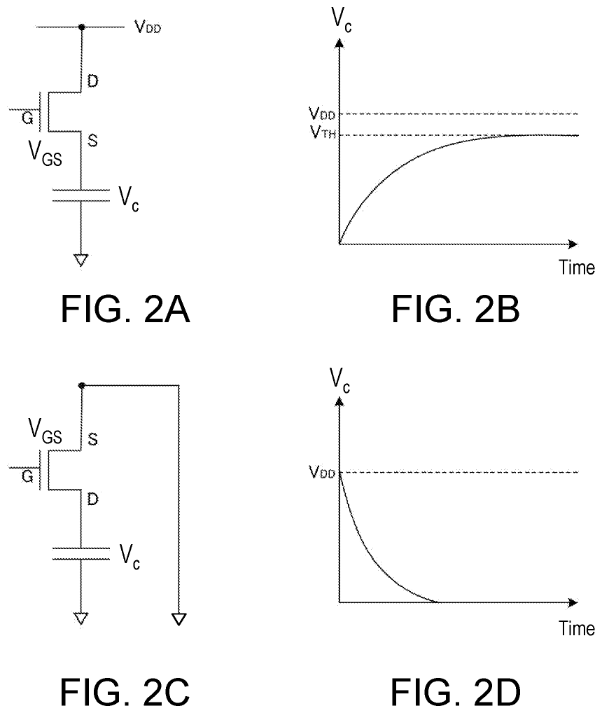

Here, the amplifier characteristics are described with reference to FIG. 2A to FIG. 2D.

Amplifiers include class A amplifiers which include one amplifying element, class B amplifiers which include two amplifying elements, in which the two amplifying elements are operated in a push-pull manner, and class AB amplifiers. Examples of the amplifying element include a metal oxide semiconductor field effect transistor (MOSFET) such as PMOS and NMOS.

Among them, in the case where a class A amplifier is used in input to a sampling circuit, due to a circuit structure of the amplifier, settling time may differ between a case where an output voltage of the sampling circuit is lowered from a high voltage to a low voltage and a case where the output voltage is raised from a low voltage to a high voltage. In the present specification, such characteristics of the class A amplifier are referred to as “amplifier characteristics.”

Specifically, a class A amplifier including a PMOS and a class A amplifier including an NMOS have completely opposite amplifier characteristics. In the class A amplifier including a PMOS, the settling time increases in the case where the output voltage is lowered, and the settling time decreases in the case where the output voltage is raised. In contrast, in the class A amplifier including an NMOS, the settling time increases in the case where the output voltage is raised, and the settling time decreases in the case where the output voltage is lowered.

The reason why such amplifier characteristic occur is briefly described using the class A amplifier including an NMOS as an example. As illustrated in FIG. 2A, an NMOS transistor is first turned off in advance, the drain is fixed at V_{DD}, and the source is connected to a capacitor discharged to 0 V in advance. When the gate is set to H from this state and turned on, at that moment, V_{GS}=V_{DD} and the NMOS transistor starts charging the capacitor.

Assuming that the voltage of the capacitor is V_{c}, as illustrated in FIG. 2B, V_{GS}=V_{DD}−V_{c}, and as V_{c} increases, V_{GS} decreases. After this, V_{c} does not rise to V_{DD} and stops at V_{DD}−V_{TH} (threshold). At this time, since V_{GS}=V_{DD}−(V_{DD}−V_{TH})=V_{TH}, the NMOS transistor is turned off and remains stopped without allowing any more current to flow. That is, since V_{GS} changes, it takes time for V_{c} to become constant.

On the other hand, as illustrated in FIG. 2C, next, the source is fixed at GND and the drain is connected to a capacitor charged to V_{DD}. Then, the gate is turned on and it is the source that is fixed at GND, V_{GS}=V_{DD} is fixed and does not change. As illustrated in FIG. 2D, the NMOS transistor continues to allow current to flow until V_{c} becomes 0 V. That is, since V_{GS} is constant, V_{c} becomes constant in a short time.

According to the above, in the class A amplifier including an NMOS, the settling time increases in the case where the output voltage is raised, and the settling time decreases in the case where the output voltage is lowered. For the same reason as this, in the class A amplifier including a PMOS, the settling time increases in the case where the output voltage is lowered, and the settling time decreases in the case where the output voltage is raised.

### Principle of Shortening Settling Time

First, a case is described where the amplifier 16 is a class A amplifier including a PMOS and an output voltage Vₒᵤₜ is set to 4 V. The class A amplifier including a PMOS has a characteristic that the settling time decreases in the case where the output voltage is raised and the settling time increases in the case where the output voltage is lowered. Accordingly, the reference potential V_{ref} is set to GND, and the switch SW3 is turned on to set the holding voltage to 0 V. When the switch SW3 is turned off and the switch SW2 is turned on, since the amplifier 16 raises the output voltage from 0 V to 4 V, the settling time is shorter than that in the case where the output voltage is lowered from 5 V to 4 V.

Next, a case is described where the amplifier 16 is a class A amplifier including an NMOS and the output voltage Vₒᵤₜ is set to 4 V. The class A amplifier including an NMOS has a characteristic that the settling time decreases in the case where the output voltage is lowered and the settling time increases in the case where the output voltage is raised. Accordingly, the reference potential V_{ref} is set to a voltage (for example, 5 V) higher than 4 V, and the switch SW3 is turned on to set the holding voltage to 5 V. When the switch SW3 is turned off and the switch SW2 is turned on, since the amplifier 16 lowers the output voltage from 5 V to 4 V, the settling time is shorter than that in the case where the output voltage is raised from 0 V to 4 V.

In the following, embodiments will be described in which two amplifier systems, such as an amplifier with an input voltage of 1 V and an amplifier with an input voltage of 4 V, are switched and used as an input voltage of the sampling circuit 10.

### First Embodiment

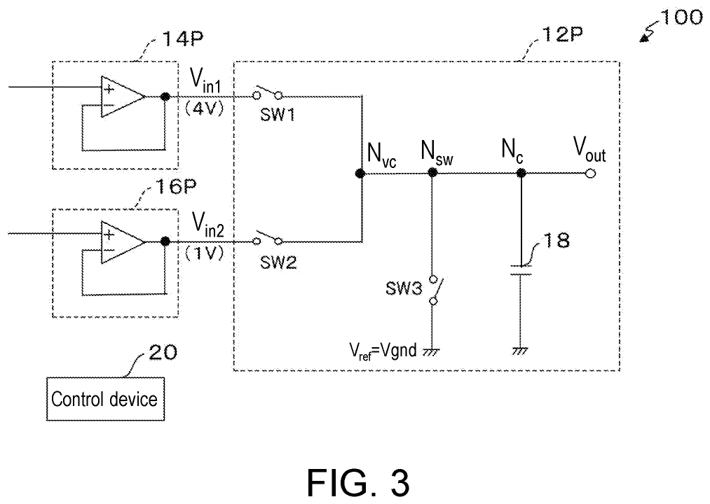

A configuration of a sampling circuit according to a first embodiment is described with reference to FIG. 3.

A sampling circuit 100 according to the first embodiment has a circuit configuration in the case of using the class A amplifier including a PMOS.

The sampling circuit 100 includes a sampling circuit part 12P, an amplifier 14P, and an amplifier 16P. As illustrated, the amplifier 14P and the amplifier 16P are amplifiers including a negative feedback circuit. The sampling circuit part 12P includes a switch SW1, the switch SW2, the switch SW3, and the capacitor 18. Each of the switch SW1, the switch SW2, and the switch SW3 is a semiconductor switch. The sampling circuit 100 includes the control device 20 that controls on/off of each of the switch SW1, the switch SW2, and the switch SW3.

The amplifier 14P is a class A amplifier including a PMOS, and an input voltage Vᵢₙ₁ to the sampling circuit part 12P is 4 V. The amplifier 14P is connected to a node N_{vc} via the switch SW1. The switch SW1 is a switch that switches input from the amplifier 14P.

The amplifier 16P is a class A amplifier including a PMOS, and an input voltage Vᵢₙ₂ to the sampling circuit part 12P is 1 V. The amplifier 16P is connected to the node N_{vc} via the switch SW2. The switch SW2 is a switch that switches input from the amplifier 16P.

The node N_{vc} is connected to an output terminal of sampling circuit 100. The capacitor 18 has one end connected to a node N_{c}between the node N_{vc} and the output terminal, and has the other end grounded. The switch SW3 is a switch for adjusting the holding voltage of the capacitor 18. The switch SW3 has one end connected to a node N_{sw} between the node N_{vc} and the node N_{c}, and has the other end grounded. Potentials at the node N_{vc}, the node N_{sw}, the node N_{c}, and the output terminal are equal to the holding voltage of the capacitor 18.

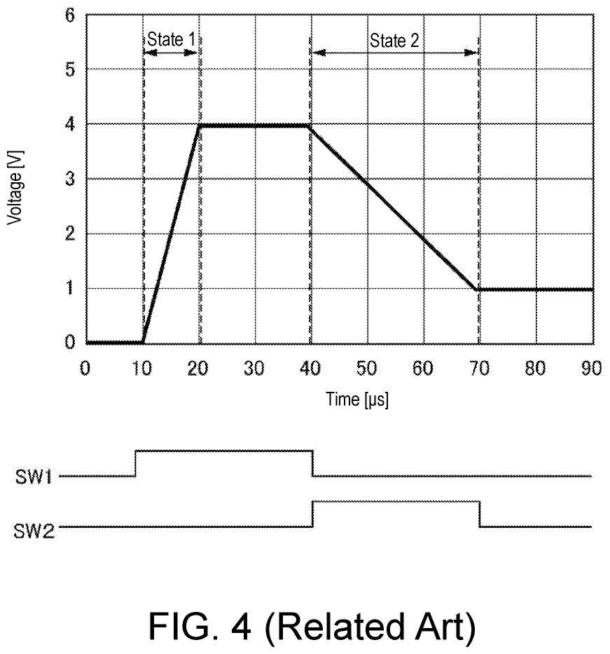

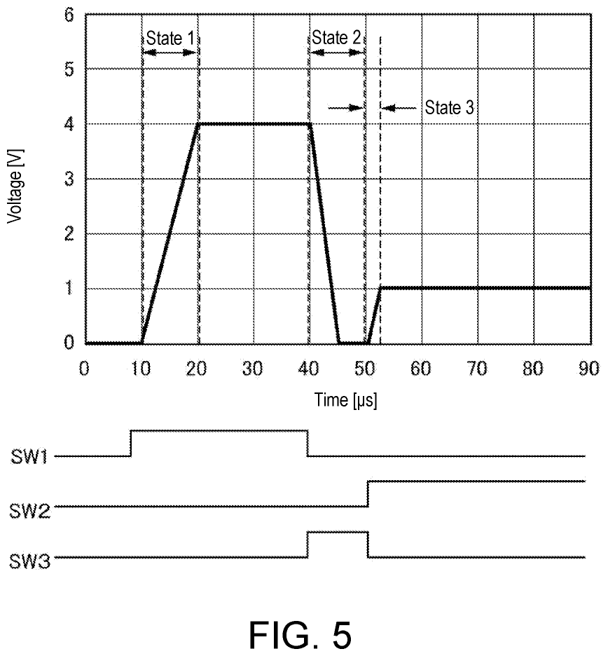

Next, an operation of the sampling circuit according to the first embodiment is described with reference to FIG. 4 and FIG. 5. The vertical axis of the graphs illustrated in FIG. 4 and FIG. 5 indicates voltage V at the node N_{vc}, and the horizontal axis indicates time (μs: microseconds). In each drawing, a timing chart indicating on/off timing of each switch is also described.

First, for comparison, an operation state of a conventional sampling circuit is described with reference to FIG. 4. The conventional sampling circuit has the same configuration as the sampling circuit illustrated in FIG. 3 except for not including the switch SW3, and is therefore described as having the circuit configuration illustrated in FIG. 3 with the switch SW3 not operated.

In the conventional sampling circuit, in “state 1” in which the switch SW1 is on and the switch SW2 is off, the capacitor 18 is charged by an input voltage from the amplifier 14P, and the voltage V at the node N_{vc} becomes 4 V. Next, in “state 2” in which the switch SW1 is off and the switch SW2 is on, the capacitor 18 is charged by the input voltage from the amplifier 16P, and the voltage V at the node N_{vc} becomes 1 V.

Since the amplifier 14P and the amplifier 16P are class A amplifiers including a PMOS, while the settling time is short in the case where the output voltage is raised from 0 V to 4 V by the amplifier 14P, the settling time increases in the case where the output voltage is lowered from 4 V to 1 V by the amplifier 16P. When the settling time increases, it becomes necessary to take a long time to start sampling.

Next, with reference to FIG. 5, an operation state of the sampling circuit 100 according to the first embodiment illustrated in FIG. 3 is described. In the sampling circuit 100, in “state 1” in which the switch SW1 is on, the switch SW2 is off, and the switch SW3 is off, the capacitor 18 is charged by the input voltage from the amplifier 14P, and the voltage V at the node N_{vc} becomes 4 V.

Next, the switch SW1 is turned off and the switch SW3 is turned on. In “state 2” in which the switch SW1 is off, the switch SW2 is off, and the switch SW3 is on, one end of the capacitor 18 is connected to the reference potential part, charges accumulated in the capacitor 18 are discharged through the switch SW3, and the voltage V at the node N_{vc} becomes 0 V.

Next, the switch SW3 is turned off and the switch SW2 is turned on. In “state 3” in which the switch SW1 is off, the switch SW2 is on, and the switch SW3 is off, the capacitor 18 is charged by the input voltage from the amplifier 16P, and the voltage V at the node N_{vc} becomes 1 V.

By turning on the switch SW3 and discharging the charges accumulated in the capacitor 18 before turning on the switch SW2, the amplifier 16P raises the output voltage Vₒᵤₜ from 0 V to 1 V. As a result, as can be seen from FIG. 4 and FIG. 5, the settling time until the output voltage Vₒᵤₜ of the sampling circuit 100 becomes stable is shorter than that in the case where the output voltage Vₒᵤₜ is lowered from 4 V to 1 V.

The duration of the state 2 in FIG. 4 is about 30 μs, and the duration of the state 3 in FIG. 5 is about 3 μs. According to the first embodiment, the settling time is reduced to 1/10. The duration of the state 2 in FIG. 5, that is, the time required to discharge the charges of the capacitor 18 is about 10 μs. Accordingly, a combined duration of the state 2 and the state 3 is about 13 μs. According to the first embodiment, the time required to change the output voltage Vₒᵤₜ from 4 V to 1 V becomes half or less.

As described above, in the sampling circuit 100 according to the first embodiment, before charging with the amplifier 16P, by adjusting the holding voltage of the capacitor 18 and converting a falling phase into a rising phase according to the characteristics (that is, the settling time is short in the case where the output voltage is raised, and the settling time is long in the case where the output voltage is lowered) of the amplifier 16P, the settling time can be shortened.

Generally, to reduce the settling time of an amplifier, solutions are taken such as increasing current consumption of the amplifier or increasing the number of output transistors to increase the circuit area and current consumption. According to the first embodiment, it is sufficient to only add the switch SW3, and the settling time can be shortened without increasing current consumption or increasing the circuit area.

### Modification

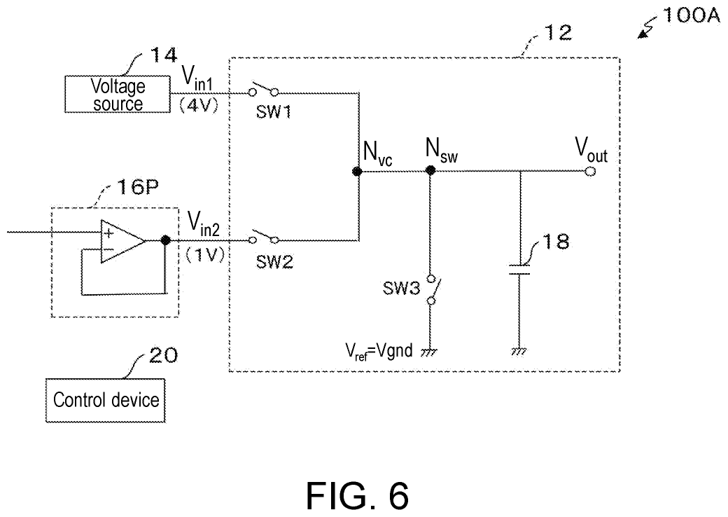

A modification of the sampling circuit according to the first embodiment is illustrated in FIG. 6.

A sampling circuit 100A illustrated in FIG. 6 has the same configuration as the sampling circuit 100 according to the first embodiment illustrated in FIG. 3 except for including, instead of the amplifier 14P, a voltage source 14 other than amplifiers. The voltage source 14 may be an ideal voltage source such as a DC power source that has zero internal resistance and always outputs a constant voltage regardless of a connected load.

In the first embodiment, an example has been described in which the sampling circuit includes two amplifier systems, namely the amplifier 14P and the amplifier 16P. However, the amplifier 14P serves to make the holding voltage of the capacitor 18 different from the input voltage of the amplifier 16P. Accordingly, the amplifier 14P may be replaced with another voltage source.

### Second Embodiment

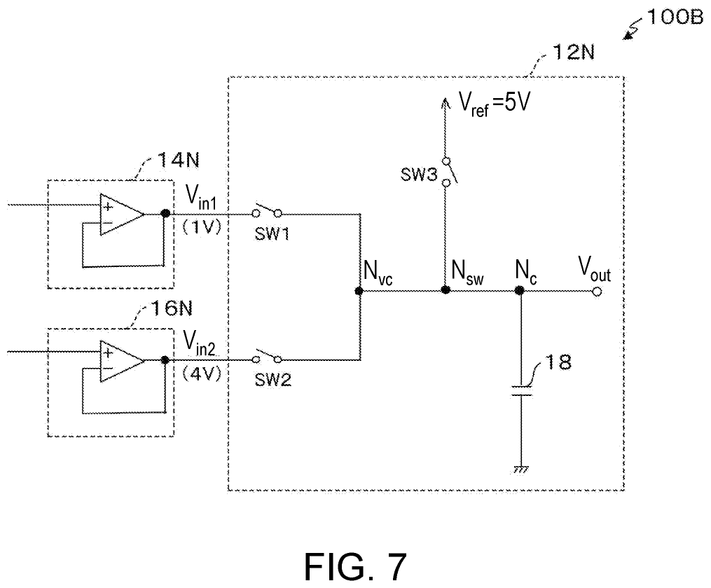

With reference to FIG. 7, a configuration of a sampling circuit according to a second embodiment is described.

A sampling circuit 100B according to the second embodiment has a circuit configuration in the case of using the class A amplifier including an NMOS.

The sampling circuit 100B includes a sampling circuit part 12N, an amplifier 14N, and an amplifier 16N. As illustrated, the amplifier 14N and the amplifier 16N are amplifiers including a negative feedback circuit. The sampling circuit part 12N includes the switch SW1, the switch SW2, the switch SW3, and the capacitor 18. Each of the switch SW1, the switch SW2, and the switch SW3 is a semiconductor switch. The sampling circuit 100B includes the control device 20 that controls on/off of each of the switch SW1, the switch SW2, and the switch SW3.

The amplifier 14N is a class A amplifier including an NMOS, and the input voltage Vᵢₙ₁ to the sampling circuit part 12N is 1 V. The amplifier 14N is connected to the node N_{vc} via the switch SW1. The switch SW1 is a switch that switches input from the amplifier 14N.

The amplifier 16N is a class A amplifier including an NMOS, and the input voltage Vᵢₙ₂ to the sampling circuit part 12N is 4 V. The amplifier 16N is connected to the node N_{vc} via the switch SW2. The switch SW2 is a switch that switches input from the amplifier 16N.

The node N_{vc} is connected to an output terminal of the sampling circuit 100B. The capacitor 18 has one end connected to the node N_{c} located between the node N_{vc} and the output terminal, and has the other end grounded. The switch SW3 is a switch for adjusting the holding voltage of the capacitor 18. The switch SW3 has one end connected to the node N_{sw} between the node N_{vc} and the node N_{c}, and has the other end connected to the reference potential V_{ref} (here, 5 V).

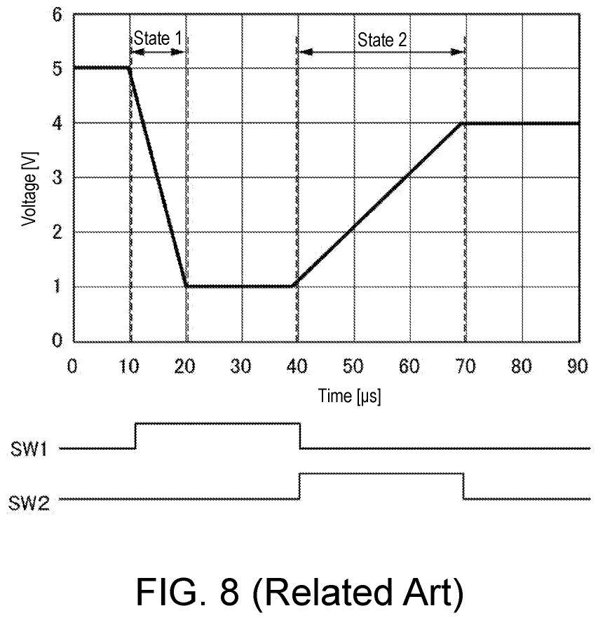

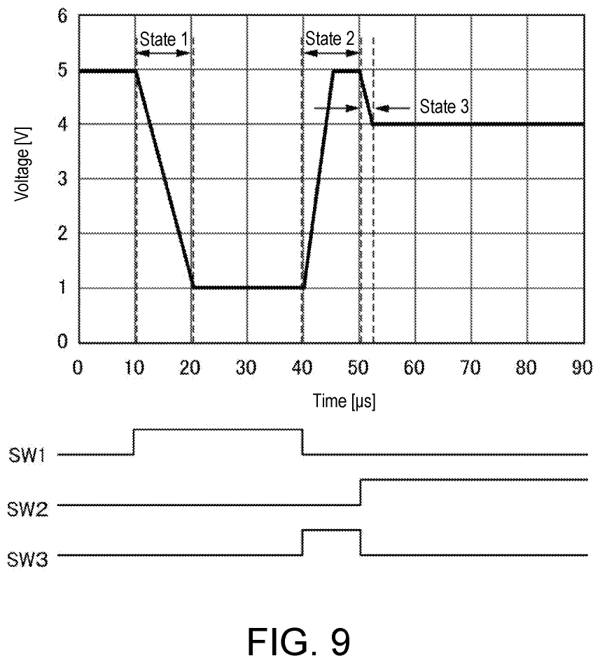

Next, an operation of the sampling circuit according to the second embodiment is described with reference to FIG. 8 and FIG. 9. The vertical axis of the graphs illustrated in FIG. 8 and FIG. 9 indicates voltage V at the node N_{vc}, and the horizontal axis indicates time. In each drawing, a timing chart indicating on/off timing of each switch is also described.

First, for comparison, an operation state of a conventional sampling circuit is described with reference to FIG. 8. The conventional sampling circuit has the same configuration as the sampling circuit illustrated in FIG. 7 except for not including the switch SW3, and is therefore described as having the circuit configuration illustrated in FIG. 7 with the switch SW3 not operated.

In the conventional sampling circuit, in “state 1” in which the switch SW1 is on and the switch SW2 is off, the capacitor 18 is charged by an input voltage from the amplifier 14N, and the voltage V at the node N_{vc} becomes 1 V. Here, an initial voltage at the node N_{vc} is set to 5 V. The voltage V at the node N_{vc} falls from 5 V to 1 V.

Next, in “state 2” in which the switch SW1 is off and the switch SW2 is on, the capacitor 18 is charged by the input voltage from the amplifier 16N, and the voltage V at the node N_{vc} becomes 4 V.

Since the amplifier 14N and the amplifier 16N are class A amplifiers including an NMOS, while the settling time is short in the case where the output voltage is lowered from 5 V to 1 V by the amplifier 14N, the settling time increases in the case where the output voltage is raised from 1 V to 4 V by the amplifier 16N. When the settling time increases, it may be necessary to take a long time to start sampling.

Next, with reference to FIG. 9, an operation state of the sampling circuit 100B according to the second embodiment illustrated in FIG. 7 is described. In the sampling circuit 100B, in “state 1” in which the switch SW1 is on, the switch SW2 is off, and the switch SW3 is off, the capacitor 18 is charged by the input voltage from the amplifier 14N, and the voltage V at the node N_{vc} becomes 1 V.

Next, the switch SW1 is turned off and the switch SW3 is turned on. In “state 2” in which the switch SW1 is off, the switch SW2 is off, and the switch SW3 is on, one end of the capacitor 18 is connected to the reference potential part, the potential of the capacitor 18 is pulled up, and the voltage V at the node N_{vc} becomes 5 V.

Next, the switch SW3 is turned off and the switch SW2 is turned on. In “state 3” in which the switch SW1 is off, the switch SW2 is on, and the switch SW3 is off, the capacitor 18 is charged by the input voltage from the amplifier 16N, and the voltage V at the node N_{vc} becomes 4 V.

By turning on the switch SW3 and pulling up the potential of the capacitor 18 before turning on the switch SW2, the amplifier 16N lowers the output voltage Vₒᵤₜ from 5 V to 4 V. As a result, as can be seen from FIG. 8 and FIG. 9, the settling time until the output voltage Vₒᵤₜ of the sampling circuit 100B becomes stable is shorter than that in the case where the output voltage Vₒᵤₜ is raised from 1 V to 4 V.

The duration of the state 2 in FIG. 8 is about 30 μs, and the duration of the state 3 in FIG. 9 is about 3 μs. According to the second embodiment, the settling time is reduced to 1/10. The duration of the state 2 in FIG. 9, that is, the time required to pull up the potential of the capacitor 18 is about 10 μs. Accordingly, a combined duration of the state 2 and the state 3 is about 13 μs. According to the second embodiment, the time required to change the output voltage Vₒᵤₜ from 1 V to 4 V becomes half or less.

As described above, in the sampling circuit 100B according to the second embodiment, before charging with the amplifier 16N, by adjusting the holding voltage of the capacitor 18 and converting a rising phase into a falling phase according to the characteristics (that is, the settling time is short in the case where the output voltage is lowered, and the settling time is long in the case where the output voltage is raised) of the amplifier 16N, the settling time can be shortened.

Generally, to reduce the settling time of an amplifier, solutions are taken such as increasing current consumption of the amplifier or increasing the number of output transistors to increase the circuit area and current consumption. According to the second embodiment, it is sufficient to only add the switch SW3, and the settling time can be shortened without increasing current consumption or increasing the circuit area.

### Modification

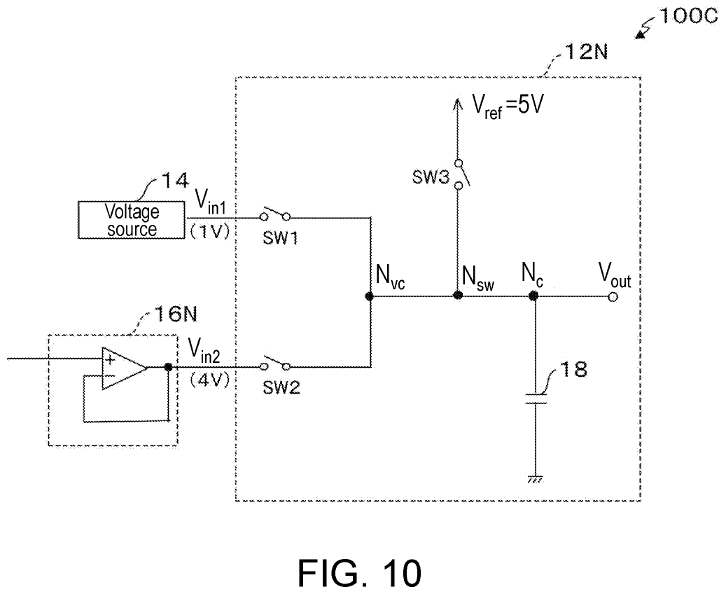

A modification of the sampling circuit according to the second embodiment is illustrated in FIG. 10.

A sampling circuit 100C illustrated in FIG. 10 has the same configuration as the sampling circuit 100B according to the second embodiment illustrated in FIG. 7 except for including, instead of the amplifier 14N, the voltage source 14 other than amplifiers. The voltage source 14 may be, for example, an ideal voltage source such as a DC power source.

### Other Modifications

The configuration of the sampling circuit and the control method thereof described in the above embodiments is an example. It goes without saying that the configuration may be changed without departing from the spirit of the present disclosure.

For example, an example has been described in which the class A amplifier including a PMOS or the class A amplifier including an NMOS is used in input to the sampling circuit. However, the amplifier is not limited to the above. The present disclosure can also be applied to cases of using an amplifier having the same characteristics as the class A amplifier including a PMOS or an amplifier having the same characteristics as the class A amplifier including an NMOS for input to the sampling circuit.

The sampling circuit according to the present embodiment can be applied to a sampling circuit used in a capacitive digital-to-analog converter (DAC) in an analog-to-digital converter (ADC). Specific timing of on/off control of each switch of the sampling circuit is set depending on the application.

What is claimed is:

1. A sampling circuit comprising:
an amplifier, having a characteristic that settling time in a case where an output voltage of the sampling circuit is lowered and the settling time in a case where the output voltage is raised are different;
a capacitor, charged by an input voltage from the amplifier;
a first switch, switching a connection state between an output of the amplifier and the capacitor;
a second switch, connected in parallel with the capacitor, and switching a connection state between the capacitor and a reference potential part whose potential is set according to the characteristic of the amplifier; and
a control circuit, controlling switching of the first switch and the second switch, wherein
the control circuit performs a first control that switches the first switch to an off state and the second switch to an on state, connects the capacitor to the reference potential part, and sets a voltage of the capacitor to a reference potential corresponding to the characteristic of the amplifier; and
after a predetermined time has elapsed from the first control, the control circuit performs a second control that switches the first switch to the on state and the second switch to the off state, connects the amplifier to the capacitor, and charges the capacitor by the input voltage of the amplifier.

2. The sampling circuit according to claim 1, wherein
in a case where the characteristic of the amplifier is a first characteristic that the settling time in the case where the output voltage is lowered is longer than the settling time in the case where the output voltage is raised, the potential of the reference potential part is set to a potential lower than the input voltage of the amplifier; and
in a case where the characteristic of the amplifier is a second characteristic that the settling time in the case where the output voltage is raised is longer than the settling time in the case where the output voltage is lowered, the potential of the reference potential part is set to a potential higher than the input voltage of the amplifier.

3. The sampling circuit according to claim 2, wherein
the amplifier having the first characteristic is a class A amplifier comprising a PMOS, and the amplifier having the second characteristic is a class A amplifier comprising an NMOS.

4. The sampling circuit according to claim 2, wherein
in a case where the amplifier has the first characteristic, the potential of the reference potential part is ground.

5. A sampling circuit comprising:
a voltage source, inputting a first voltage;
an amplifier, inputting a second voltage, and having a characteristic that settling time in a case where an output voltage of the sampling circuit is lowered and the settling time in a case where the output voltage is raised are different;
a capacitor, charged by an input voltage from the voltage source or the amplifier;
a first switch, switching a connection state between the voltage source and the capacitor;
a second switch, switching a connection state between the amplifier and the capacitor;
a third switch, connected in parallel with the capacitor, and switching a connection state between the capacitor and a reference potential part whose potential is set according to the characteristic of the amplifier; and
a control circuit, controlling switching of the first switch, the second switch, and the third switch, wherein
the control circuit performs a first control that switches the first switch to an on state, the second switch to an off state, and the third switch to an off state, connects the voltage source to the capacitor, and charges the capacitor to the first voltage;
after a predetermined time has elapsed from the first control, the control circuit performs a second control that switches the first switch to the off state, the second switch to the off state, and the third switch to the on state, connects the capacitor to the reference potential part, and changes a voltage of the capacitor from the first voltage to a reference potential corresponding to the characteristic of the amplifier; and
after a predetermined time has elapsed from the second control, the control circuit performs a third control that switches the first switch to the off state, the second switch to the on state, and the third switch to the off state, connects the amplifier to the capacitor, and charges the capacitor to the second voltage.

6. The sampling circuit according to claim 5, wherein
in a case where the characteristic of the amplifier is a first characteristic that the settling time in the case where the output voltage is lowered is longer than the settling time in the case where the output voltage is raised, the potential of the reference potential part is set to a potential lower than the input voltage of the amplifier; and
in a case where the characteristic of the amplifier is a second characteristic that the settling time in the case where the output voltage is raised is longer than the settling time in the case where the output voltage is lowered, the potential of the reference potential part is set to a potential higher than the input voltage of the amplifier.

7. The sampling circuit according to claim 6, wherein
the amplifier having the first characteristic is a class A amplifier comprising a PMOS, and the amplifier having the second characteristic is a class A amplifier comprising an NMOS.

8. The sampling circuit according to claim 6, wherein
in a case where the amplifier has the first characteristic, the potential of the reference potential part is ground.

9. The sampling circuit according to claim 5, wherein
the voltage source is an amplifier having the same characteristics as the amplifier.

10. The sampling circuit according to claim 5, wherein
the voltage source is an ideal voltage source.
